(19) United States
(12) Patent Application Publication
(10) Pub. No.: US 2012/0101731 A1
(43) Pub. Date: Apr. 26, 2012

(54) Extending Data Retention of a Data Storage Device Downhole

(75) Inventor: Joseph C. Joseph, Houston, TX (US)

(73) Assignee: BAKER HUGHES INCORPORATED, Houston, TX (US)

(21) Appl. No.: 12/909,551

(22) Filed: Oct. 21, 2010

(51) Int. Cl. G06F 19/00; G06F 12/16; G11C 7/10

(52) U.S. Cl. 702/9; 365/189.17; 711/162; 711/E12.002

(57) ABSTRACT

A system and method for performing a wellbore operation is disclosed. A first memory device for storing data is provided at a downhole location, the first memory device having a first data retention time. A second memory device is provided at the downhole location, and controller is used to store data at the first memory device and to transfer the data to the second memory device at a selected time interval less than the first data retention time.

### BACKGROUND OF THE DISCLOSURE

1. Field of the Disclosure

The present disclosure relates to extending a functional lifetime of a memory device in a downhole environment.

2. Description of the Related Art

Solid state memories, such as flash memory devices, currently in use for wellbore operations are able to retain data for a relatively short time period compared to their use at the surface due to the high temperatures in the wellbore. For example, a flash memory device typically has less than 3 months of data retention time when used at 150 degrees Celsius. This potentially restricts the suitability of using flash memory devices in downhole environments because these environments typically involve high temperatures. On the other hand, it is desired to deploy such memory devices in downhole environments over time durations somewhere in the range of 5 years. The present disclosure provides a method and apparatus for storing data in such and other memory devices in a downhole environment.

### SUMMARY OF THE DISCLOSURE

In one aspect, the present disclosure provides a method of storing data, the method comprising: storing the data at a first memory location having a first data retention time; and transferring the data from the first memory location to a second memory location at a time interval less than the first data retention time.

In another aspect, the present disclosure provides an apparatus for performing a wellbore operation, the apparatus comprising a first data storage device for storing data at a first location, the first data storage device having a first data retention time; a second data storage device at a second location; and a controller configured to store data at the first data storage device and transfer the data from the first data storage device to the second data storage device at a time interval less than the first data retention time.

In yet another aspect, the present disclosure provides a method for performing a wellbore operation, the method comprising: providing a first data storage device for storing data at a first location, the first data storage device having a first data retention time; providing a second data storage device at a second location; storing a data set at the first data storage device; and transferring the data set from the first data storage device to the second data storage device at a time interval less than the first data retention time.

Examples of certain features of the apparatus and method disclosed herein are summarized rather broadly in order that the detailed description thereof that follows may be better understood. There are, of course, additional features of the apparatus and method disclosed hereinafter that will form the subject of the claims.

### BRIEF DESCRIPTION OF THE DRAWINGS

For detailed understanding of the present disclosure, references should be made to the following detailed description of the exemplary embodiment, taken in conjunction with the accompanying drawings, in which like elements have been given like numerals and wherein:

FIG. 1 shows an exemplary system in a wellbore having a data storage device suitable for storing data using the exemplary methods of the present disclosure;

FIG. 2 shows a detailed illustration of an exemplary control unit having memory locations for storing programs and data using the methods of the present disclosure; and

FIG. 3 shows a flowchart of an exemplary method of the present disclosure for storing data in a data storage device.

### DETAILED DESCRIPTION OF THE DISCLOSURE

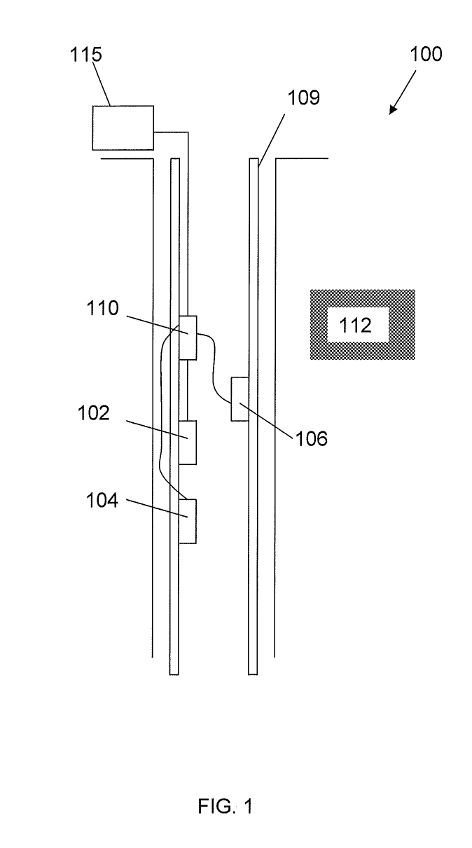

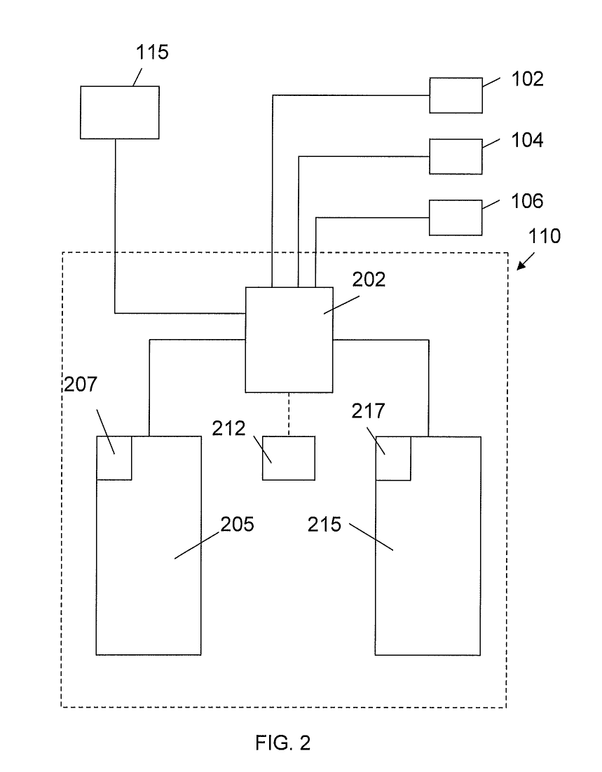

FIG. 1 shows an exemplary system 100 in a wellbore having a data storage device for storing data using the exemplary methods of the present disclosure. It is noted that although the present disclosure is described herein with respect to a data storage device on a production system, the present disclosure is equally applicable to data storage devices used with other systems. Other exemplary systems that may be suitable for use with the method of present disclosure also include, but are not limited to, a wireline system, a drilling system including measurement-while-drilling and logging-while-drilling operations, a well logging system, a system for completing a well, and a production operation system. In one aspect, the data storage device may include memory that has a data retention time that is affected by temperature or reduced due to high temperatures. In one embodiment, the data storage device includes a flash memory device. However, the type of data storage device is not limited to flash memory device and may include any suitable data storage device that may be used with the various exemplary systems disclosed herein. The exemplary system of FIG. 1 includes a casing 109 in the wellbore penetrating an earth formation 112 for the production of hydrocarbons from the earth formation. The casing includes various exemplary sensors 102, 104 and 106 which may include permanent gauges for measuring various production parameters. Exemplary sensors 102, 104 and 106 may measure, for example temperature, pressure, hydrocarbon flow, etc. In one embodiment, the various parameters as well as other data are stored in a unit 110 downhole, which unit is referred to herein as a control unit 110 but which may be a storage unit, a processor unit or any other unit having downhole functionality. The control unit 110 may be in communication with exemplary surface unit 115 and may exchange data with the surface unit 115. The control unit 110 is described in detail in FIG. 2 and may include one or more data storage devices to store data storage and/or programs. Programs in the control unit 110 may be used for control and operation of the various sensors, as well as for performing various wellbore operations. Illustrative example of wellbore operations may include monitoring a wellbore parameter, recording of downhole data, making a well log, a well completion operation, a drilling operation, a wireline operation, storing data relating to a measurement-while-drilling, and a production operation, for example. Additionally, programs at the control unit 115 may provide instructions for operating the methods of the present disclosure. In alternate embodiments, exemplary sensors 102, 104 and 106 may have dedicated data storage devices for storing various data and parameters downhole.

FIG. 2 shows a detailed illustration of the exemplary control unit of FIG. 1. In one embodiment, the control unit 110 includes a first data storage device 205 and a second data storage device 215 for storing programs and data. The first and second data storage device 205 and 215 may be two separate data storage devices as shown in FIG. 2 or may be two memory locations within a single data storage device.

In one embodiment, data may be stored at the first data storage device 205. Upon storing at the first data storage device 205, the data may be transferred to the second data storage device 215 at a time that is less than a data retention time of the first data storage device 205. Upon storing the data at the second data storage device 215, the data may be transferred to another data storage device at a time that is less than a data retention time of the second data storage device. In one aspect, the data may be transferred from the second data storage device to a third data storage device 212. In another aspect, the data may be transferred from the second data storage device back to the first data storage device 205. This process may be continued indefinitely so that the data is copied out of one data storage device and stored in another data storage device before the data can be lost, thereby extending the life of the data beyond that of at least one of the data storage devices.

The processor 202 may transfer the data at a selected time interval. For the purpose of maintaining data beyond a data retention time of a data storage device, the duration of the selected time interval is less than the data retention time of the data storage device. Therefore, the data is transferred to another data storage device before data degradation occurs at its current memory location. For example, current flash memory devices have a data retention time of about 3 months at 150 degrees C. (i.e., downhole environmental temperatures). Therefore, a time interval may be selected to transfer data every 30 days. In this manner, the maximum time data is stored in any given memory location is 30 days. However, by repeating the process of tracking a selected time interval and then transferring data to another data storage device, the data itself can be retained for a time period exceeding the data retention time of any of the first and second data storage devices. Continuing with the above example, current flash memories can have more than 1000 write cycles at 150 degrees C. Therefore, if data is transferred every 30 days, the data can be retained for about 80 years, well beyond the 3 months data retention time of a selected flash memory device.

To initiate the transfer, a signal may be received at the processor. In various embodiments, the signal may be a boot signal or a transfer signal received from a separate location such as a surface location. The signal may be alternatively initiated from processor 202 tracking time with respect to the selected time interval. A pre-determined transfer time interval may be stored at the processor.

In another embodiment, data may be stored at first and second data storage devices 205 and 215. The data may be received, for example, from the exemplary sensors 102, 104 and 106 at processor 202 which stores a first set of data 209 at the first data storage device 205 and a second set of data 206 at the second data storage device 215. In one embodiment, the second set of data 219 is substantially the same as the first set of data 209. In one aspect, the exemplary first and second sets of data 209 and 219 are stored substantially simultaneously at the first and second data storage devices 205 and 215. First data storage device 205 may also store a first set of programs 207 which may be used by processor 202 to operate the exemplary data storage methods of the present disclosure. Second data storage device 215 may also store a second set of programs 217 that is the same as the first set of programs 207. The first and second set of programs 207 and 217 may also provide programs for other downhole applications, such as executing a function at a downhole apparatus or obtaining data.

In one embodiment, processor 202 performs a method of swapping the contents of the first and second data storage devices 205 and 215. In other words, the first data set is copied to second data storage device 215 and the second data set is copied to the first data storage device 205. Any method of swapping may be used, including copying the contents of the first data storage device 205 to a temporary data storage device (i.e., memory device 212), copying the contents of the second data storage device 215 to the first data storage device 205, and then copying the contents of the temporary data storage device 212 to the second data storage device 215.

The location of the second memory device may be varied. In various embodiments, the second memory device may be at a location such as a downhole location, a downhole location proximate the location of the first memory device, a surface location, and the same location as the first location.

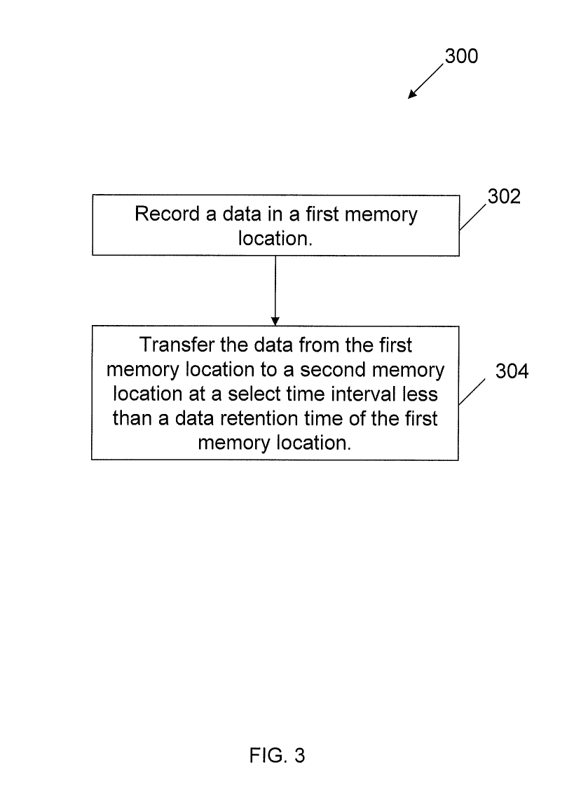

FIG. 3 shows a flowchart 300 of an exemplary method of the present disclosure for storing data in a memory device downhole. In Box 302, a first set of data is stored at a first data storage device. In Box 304, data is transferred from the first data storage device to a second data storage device at a selected time interval which is less than a data retention time of the first data storage device.

Thus, in one embodiment, the present disclosure provides a method of storing data, including storing the data at a first memory location having a first data retention time and transferring the data from the first memory location to a second memory location at a time interval less than the first data retention time. In one aspect, the first data retention time is a function of temperature. In another aspect, the second memory location has a second data retention time, the data from the second memory location is transferred to a third memory location or back to the first memory location at a time interval less than the second data retention time. In another aspect, a substantial copy of the data at the first memory location is stored at the second memory location. In this aspect, transferring the data further includes swapping the data at the first memory location with the copy of the data at the second memory location. The data may be transferred in response to a signal. The signal may include one of (a) a boot signal, (b) a signal from a surface location, and (c) a signal from a processor tracking time. The first memory location and the second memory location are typically at a location in a downhole environment.

In another embodiment, the present disclosure provides an apparatus for performing an operation downhole. The exemplary apparatus includes a first data storage device configured to store data at a first location, the first memory device having a first data retention time, a second data storage device at a second location, and a controller configured to store data at the first data storage device and transfer the data from the first data storage device to the second data storage device at a time interval less than the first data retention time. The first data retention time may be a function of temperature. In one aspect, second data storage device has a second data retention time, wherein the controller is further configured to transfer the data from the second data storage device to a third data storage device or back to the first data storage device at a time interval less than the second data retention time. In another aspect, the second data storage device stores a substantial copy of the data at the first memory device and the controller transfers data by swapping the data at the first data storage device with the copy of the data at the second memory device. The controller may transfer the data in response to a signal, such as a boot signal, a signal sent from a surface location, or a signal from a processor tracking time. The first data storage device and the second data storage typically include a solid-state memory device.

In yet another aspect, the present disclosure provides a method for performing a wellbore operation. The exemplary method includes providing a first data storage device for storing data at a first downhole location, the first memory device having a first data retention time; providing a second data storage device at a second location; storing a data set at the first data storage device; and transferring the data set from the first data storage device to the second data storage device at a time interval less than the first data retention time. In one aspect, the first data retention time is a function of temperature. In another aspect, the second memory device has a second data retention time and the method further includes transferring the data set from the second data storage device to the first data storage device at a time interval less than the second data retention time. In another aspect, the second data storage device stores a substantial copy of the data at the first data storage device and transferring the data includes swapping the data at the first data storage device with the copy of the data at the second data storage device. The second location may be one of: (a) a downhole location; (b) a downhole location proximate the first location; (c) a surface location; and (d) same as the first location. The wellbore operation may be selected from a group consisting of: (a) monitoring a wellbore parameter; (b) recording of downhole data; (c) making a well log; (d) a well completion operation; (e) a drilling operation; (f) a wireline operation; (g) storing data relating to a measurement-while-drilling; and (h) a production operation.

While the foregoing disclosure is directed to the preferred embodiments of the disclosure, various modifications will be apparent to those skilled in the art. It is intended that all variations within the scope and spirit of the appended claims be embraced by the foregoing disclosure.

What is claimed is:

1. A method of storing data, comprising:
storing the data at a first memory location having a first data retention time; and
transferring the data from the first memory location to a second memory location at a time interval less than the first data retention time.

2. The method of claim 1, wherein the first data retention time is a function of temperature.

3. The method of claim 1, wherein the second memory location has a second data retention time, the method further comprising transferring the data from the second memory location to a third memory location at a time interval less than the second data retention time.

4. The method of claim 1, wherein the second memory location has a second data retention time and wherein the method further comprising transferring data from the second memory location to the first memory location at a time interval less than the second data retention time.

5. The method of claim 1, wherein a substantial copy of the data at the first memory location is stored at the second memory location and wherein transferring the data further comprises swapping the data at the first memory location with the copy of the data at the second memory location.

6. The method of claim 1 further comprising transferring the data in response to a signal.

7. The method of claim 6, wherein the signal comprises one of (a) a boot signal, (b) a signal from a surface location, and (c) a signal from a processor tracking time.

8. The method of claim 1, wherein the first memory location and the second memory location are at a location in a downhole environment.

9. An apparatus for performing an operation downhole, comprising:
a first data storage device configured to store data at a first location, the first memory device having a first data retention time;
a second data storage device at a second location; and
a controller configured to store data at the first data storage device and transfer the data from the first data storage device to the second data storage device at a time interval less than the first data retention time.

10. The apparatus of claim 9, wherein the first data retention time is a function of temperature.

11. The apparatus of claim 9, wherein the second data storage device has a second data retention time and wherein the controller is further configured to transfer the data from the second data storage device to a third data storage device at a time interval less than the second data retention time.

12. The apparatus of claim 9, wherein the second data storage device has a second data retention time and wherein the controller is further configured to transfer the data from the second data storage device to the first data storage device at a time interval less than the second data retention time.

13. The apparatus of claim 9, wherein the second data storage device is configured to store a substantial copy of the data at the first memory device and wherein the controller is configured to swap the data at the first data storage device with the copy of the data at the second memory device.

14. The apparatus of claim 9, wherein the controller is further configured to transfer the data in response to a signal.

15. The apparatus of claim 14, wherein the signal is selected from a group consisting of (a) a boot signal, (b) a signal sent from a surface location, and (c) a signal from a processor tracking time.

16. The apparatus of claim 9, wherein the first data storage device and the second data storage comprise a solid-state memory device.

17. A method for performing a wellbore operation, comprising:
providing a first data storage device for storing data at a first downhole location, the first memory device having a first data retention time;
providing a second data storage device at a second location;
storing a data set at the first data storage device; and
transferring the data set from the first data storage device to the second data storage device at a time interval less than the first data retention time.

18. The method of claim 17, wherein the first data retention time is a function of temperature.

19. The method of claim 17, wherein the second memory device has a second data retention time and wherein the method further comprises transferring the data set from the second data storage device to the first data storage device at a time interval less than the second data retention time.

20. The method of claim 17 wherein the second data storage device stores a substantial copy of the data at the first data storage device, wherein transferring the data further comprises swapping the data at the first data storage device with the copy of the data at the second data storage device.

21. The method of claim 17 wherein the second location is selected from one of: (a) a downhole location; (b) a downhole location proximate the first location; (c) a surface location; and (d) same as the first location.

22. The method of claim 17, wherein the wellbore operation is selected from a group consisting of: (a) monitoring a wellbore parameter; (b) recording of downhole data; (c) making a well log; (d) a well completion operation; (e) a drilling operation; (f) a wireline operation; (g) storing data relating to a measurement-while-drilling; and (h) a production operation.
